(19) United States
(12) Patent Application Publication
(10) Pub. No.: US 2024/0421516 A1
(43) Pub. Date: Dec. 19, 2024

(54) TECHNIQUES FOR A MODULE CONNECTOR DESIGN TO IMPROVE PIN CONNECTION

(71) Applicant: Intel Corporation, Santa Clara, CA (US)

(72) Inventors: Xiang LI, Portland, OR (US); George VERGIS, Portland, OR (US)

(21) Appl. No.: 18/821,088

(22) Filed: Aug. 30, 2024

(51) Int. Cl. H01R 12/70; H01R 13/20; H05K 1/11

(52) U.S. Cl. CPC H01R 12/707; H01R 13/20; H05K 1/111; H05K 2201/10159

(57) ABSTRACT

Examples include techniques for a module connector design to improve pin connection. The techniques include covering top and bottom cavities of a connector that includes connector pins arranged to be coupled with a printed circuit board via a reflow soldering process to prevent a film from forming on the connector pins during or after the reflow soldering process.

### TECHNICAL FIELD

Descriptions are generally related to techniques for improving pin connections for connectors connected to a printed circuit board based on surface mount technology (SMT).

### BACKGROUND

Various technologies exist for connecting devices, such as cards and modules, with a printed circuit board (PCB), such as a motherboard. While it is possible to couple electronic components directly to a motherboard it is common to use a connector between the motherboard and the card or module to enable removably coupling the card or module with the motherboard.

In some configurations for connectors, a connector can include connector pins that contact conductive leads or contacts on the card or module and on the motherboard. In some examples, connector pins can connect with conductive leads on the motherboard through an SMT pad. A lower portion of each connector pin can be soldered on to a motherboard via the SMT pad and a reliable connection can be formed once the solder joint completes a reflow soldering process that includes heating up the connection to temperatures above 200 degrees Celsius for a period of time during the reflow soldering process.

### BRIEF DESCRIPTION OF THE DRAWINGS

FIG. 1 illustrates an example first system.

FIG. 2 illustrates an example expanded view of the first system.

FIG. 3 illustrates an example scanning electron microscopy-energy dispersive x-ray (SEM-EDX) analysis.

FIG. 4 illustrates example top and bottom views of a connector.

FIG. 5 illustrates an example of uncovered and covered top cavity views of the connector.

FIG. 6 illustrates an example of uncovered and covered bottom cavity views of the connector.

FIG. 7 illustrates an example process flow.

FIG. 8 illustrates an example second system.

### DETAILED DESCRIPTION

As mentioned previously, devices, such as cards and modules, can be connected with a printed circuit board (PCB), such as a motherboard via connector pins that contact conductive leads or contacts on the card or module on the motherboard. Also, a lower portion of each connector pin can be soldered on to a motherboard through a (surface mount technology) (SMT) pad using a reflow soldering process that includes heating up the connection between the lower portion of the connector pin and the SMP pad to temperatures above 200 Celsius for a period of time during the reflow soldering process. When a module, such as but not limited to, a memory module (e.g., a dual in-line memory module (DIMM)), is inserted into a connecter that has been connected to a motherboard, the connector pin wipes over and makes a connection with a contact on the memory module that can be referred to as a gold finger (GF). However, the reflow soldering process used to connect the connector pin to the motherboard can cause a non-conductive film to form on at least a portion of the connector pin. The source of the non-conductive film can be due to organic-based dust or resin that may have vaporized during the reflow soldering process that can include heating the connector pin and a solder ball or paste of an SMP pad to temperatures between 200 to 260 Celsius. So, due to the non-conductive film, at a system application of the memory mode, a failure can occasionally happen when the memory module is initialized or booted. An operator may then have to physically remove the memory module and insert the module back a number of times to eventually rub off enough of the non-conductive film to get the memory module to form an adequate electrical/conductive connection between the connector pin and the memory module's GF in order to get the memory module to properly boot or initialize. This removing and reinserting of a memory module is typically called a reseating issue. As described more below, techniques are described that can reduce or eliminate formation of a non-conductive film on a connector pin during or after a reflow process in order to improve a pin connection and possibly avoid the reseating issue.

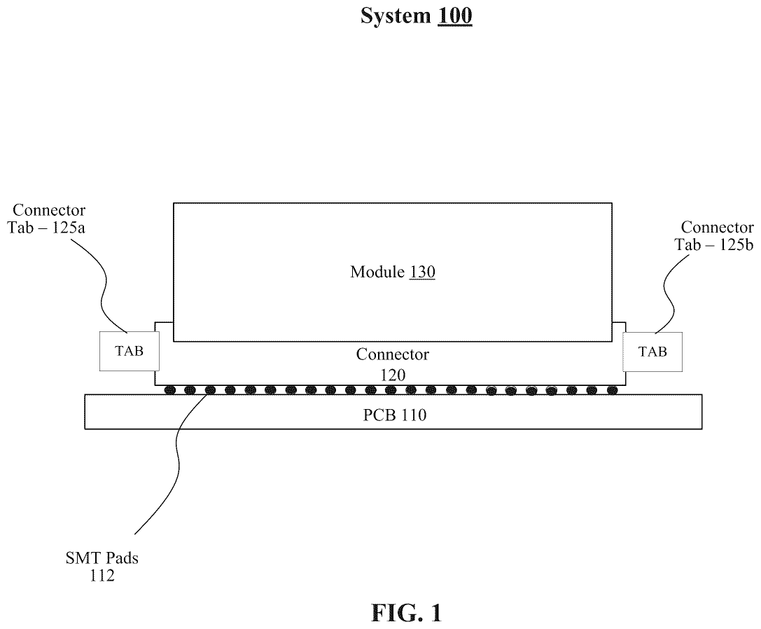

FIG. 1 is a block diagram of an example system 100. As shown in FIG. 1, system 100 includes a connector 120 coupled with a printed circuit board (PCB) 110 (e.g., a motherboard). Connector 120 includes connector pins (not shown in FIG. 1) that can be arranged to physically and electrically contact with PCB 110 via surface mount technology (SMT) pads 112 (e.g., a solder pad) disposed on a surface of PCB 110. Also, as shown in FIG. 1, connector 120 can include connector tabs 125a and 125b. In some examples, connectors tabs 125a and 125b can be arranged to secure a receipt of a module 130 into a cavity (not shown in FIG. 1) located in a top portion of a connector housing for connector 120. For these examples, the connector pins of connector 120 can couple with contacts on module 130 to provide an electrical contact between module 130 and PCB 110 through the connector pins and SMT pads 112.

In some examples, module 130 can be a memory module that can include non-volatile or volatile memory included in one or more memory devices or die. For example, module 130 can be a dual in-line memory module (DIMM) that includes volatile memory or a solid state drive (SSD) that includes non-volatile memory. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (dynamic random-access memory), or some variant such as synchronous DRAM (SDRAM). Module 130 that is a memory module can include volatile memory compatible with a number of memory technologies, such as DDR3 (double data rate version 3), JESD79-3F, originally released by the Joint Electronic Device Engineering Council (JEDEC) in July 2012, DDR4 (DDR version 4), JESD79-4C, originally published in January 2020, DDR5 (DDR version 5), JESD79-5C, originally published in April 2024, LPDDR3 (Low Power DDR version 3), JESD209-3C, originally published in August 2015, LPDDR4 (LPDDR version 4), JESD209-4D, originally published by in June 2021, LPDDR5 (LPDDR version 5), JESD209-5C, originally published in June 2023, WIO2 (Wide Input/output version 2), JESD229-2, originally published in August 2014, HBM (High Bandwidth Memory), JESD235B, originally published in December 2018, HBM2 (HBM version 2), JESD235D, originally published in January 2020, or HBM3 (HBM version 3), JESD238A, originally published in January 2023, or other memory technologies or combinations of memory technologies, as well as technologies based on derivatives or extensions of such above-mentioned specifications. The JEDEC standards or specifications are available at www.jedec.org.

In examples where module 130 is a memory module and includes volatile memory. The volatile memory can be arranged to operate according to a JEDEC specification such as the DDR5 specification and connector 120 can also be arranged to operate according to the DDR5 specification. Examples are not limited to the DDR5 specification. Memory module 130 and connector 120 can be arranged to operate according to any one of the above mentioned JEDEC specifications.

According to some examples, module 130 can be a card arranged to operate according to a Peripheral Component Interconnect Special Interest Group (PCI-SIG) specification such as PCI Express Base Specification, Revision 6.2, originally published in February 2024. For these examples, the card can be referred to as a PCle card and connector 120 can be referred to as a PCIe connector.

In other examples, connector 120 and module 130 can be arranged to operate according to another PCI-SIG specification such as the PCI Express M.2 Specification, Revision 5.1, originally published in May 2024. Connector 120 arranged to operate according the PCI Express M.2 specification can be referred to as an M.2 connector. Also, module 130 can be configured in a form factor described in the PCI Express M.2 specification and can be referred to as an M.2 PCle card.

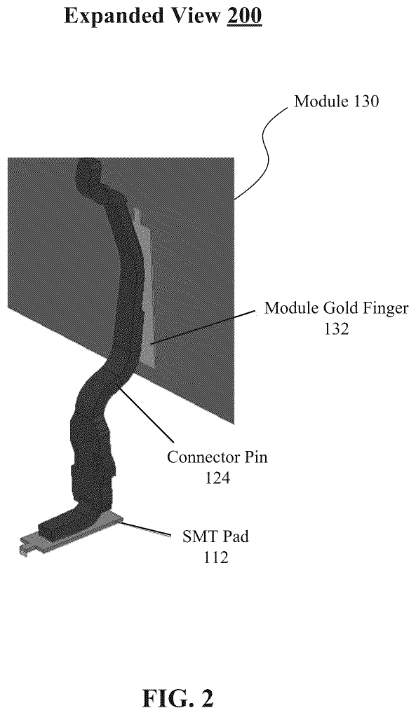

FIG. 2 illustrates expanded view 200 of a portion of system 100. In some examples, as shown in FIG. 2, expanded view 200 shows a portion of module 130 that was not visible in FIG. 1. Also, a connector pin 124 is shown in FIG. 2 as coupling with a module gold finger 132 of module 130 on an upper portion of connector pin 124 and coupling with SMT pad 112 from among SMT pads 112 on a lower portion of connector pin 124. For these examples, module gold finger 132 serves as a contact for module 130 and when module 130 is inserted in connector 120, as shown in FIG. 1, an electrical contact between module 130 and PCB 110 through connector pin 124 can be established.

According to some examples, SMT pads 112 can be physically coupled or connected with connector pins included in connector 120 such as connector pin 124 via a reflow soldering process that occurs prior to inserting module 130 in connector 120. For example, SMT pad 122 can initially be arranged as a solder ball or paste on PCB 110. The solder ball or paste can include, but is not limited to, a tin-lead solder that includes a combination of tin (Sn) and lead (Pb) or can include an alloy type of lead-free solder compatible with pure tin or gold that includes a combination of SN, gold (Au) and copper (Cu). A solder reflow oven can be used during a reflow process to generate sufficient temperatures (e.g., 200 to 260 Celsius) to cause the solder ball or paste to temporarily melt or flow around the lower portion of and then allow the solder ball or paste to cool or cure to form SMT pad 112.

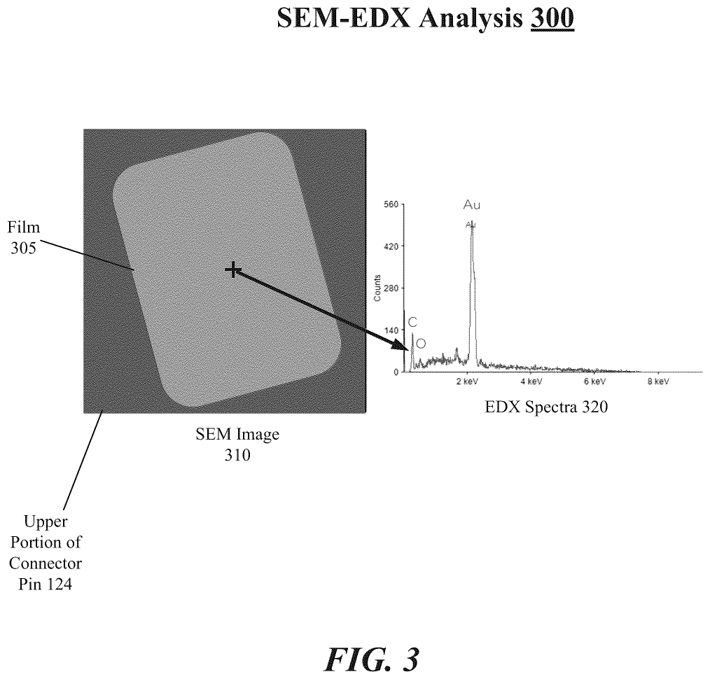

FIG. 3 illustrates an example scanning electron microscopy-energy dispersive x-ray (SEM-EDX) analysis 300. In some examples, if foreign objects such as organic-based dust, pieces of plastic or resin are on or around a solder ball or paste or a lower portion of a connector pin, those foreign objects could be at least partially vaporized during a reflow soldering process. The vaporized foreign objects can cause a film to form on an upper portion of a connector pin included in a connector. For example, SEM image 310 in FIG. 3 shows a lighter-shaded film 305 at least partially covering an upper portion of connector pin 124 following a reflow soldering process to connect a lower portion of connector pin 124 to SEM pad 112. The upper portion of connector pin 124 can be arranged to couple to a contact of a module such as module gold finger 132 as shown in FIG. 2 when module 130 is inserted in connector 120.

According to some examples, an EDX spectra 320 can be generated by an energy dispersive x-ray directed at the center of film 305. For these examples, as shown in FIG. 3, EDX spectra 320 depicts a series of peaks for carbon (C), oxygen (O) and gold (Au). The C and O peaks in EDX spectra 320 can indicate a potential organic film composition for film 305 that could have been caused by foreign objects such as organic-based dust, pieces of plastic or resin that was vaporized during the above-mentioned reflow process. This organic film could at least partially prevent an electrical coupling between the upper portion of connector pin 124 and module gold finger 132. Films of a similar composition as EDX spectra 320 can form on several other connector pins included in connector 120. Thus, when module 130 is inserted into connector 120 and powered up or booted, module 130 may fail to operate as designed.

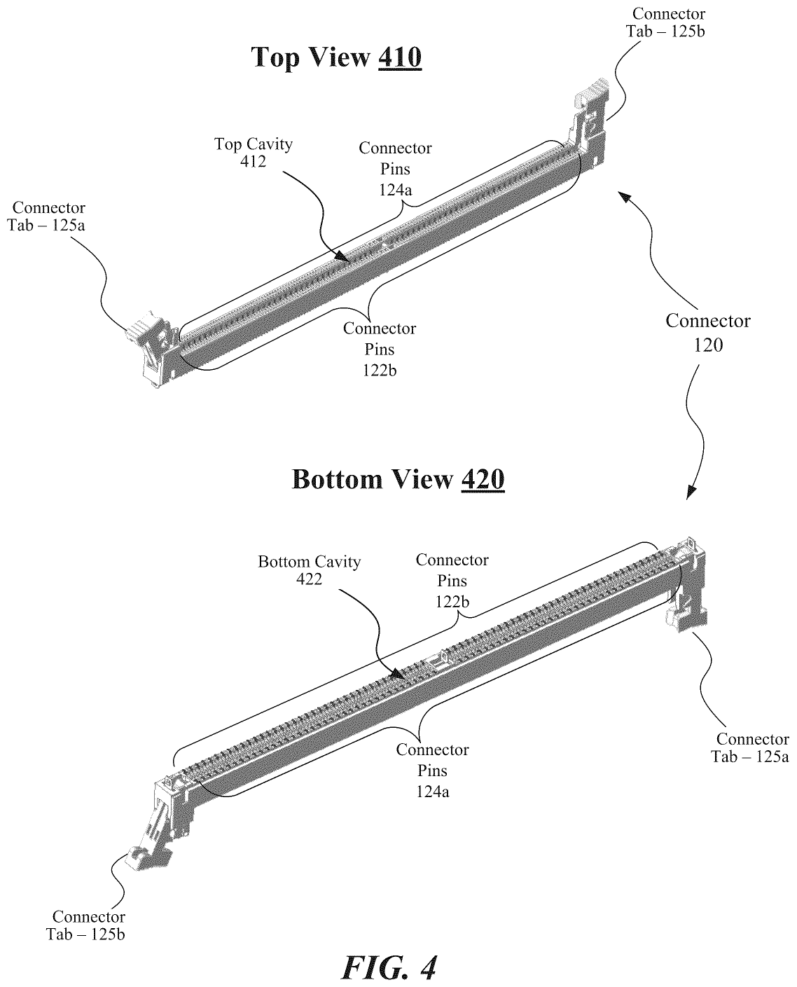

FIG. 4 illustrates example top view 410 and bottom view 420 of connector 120.

According to some examples, connector 120 can be configured to operate according to the DDR5 specification to receive a DIMM module that includes DDR5 memory. As shown in FIG. 4 for top view 410, connector 120 can include a first plurality of connector pins 124a on a first side of a connector housing of connector 120 and a second plurality of connector pins 124b on a second side of the connector housing of connector 120. According to some examples, connector tabs 125a and 125b can be arranged to secure a DIMM when inserted in a top cavity 412. The DIMM can have contacts on bottom side portions that separately couple or connect with respective upper portions of connector pins 124a and 124b when inserted in top cavity 412 and secured with connector tabs 125a and 125b.

In some examples, as shown in FIG. 4, bottom view 420 of connector 120 shows lower portions of connector pins 122a and 122b that can be arranged to separately couple with or connect to a respective SMT pad of a PCB such as an SMT pad from among SMT pads 112 of PCB 110 via a reflow soldering process. For these examples, as shown in FIG. 4, a bottom cavity 422 can be formed between the lower portions of connector pins 122a and 122b and bottom of the connector housing of connector 120.

According to some examples, top cavity 412 and bottom cavity 422 can accumulate foreign object(s) that could vaporize during a reflow soldering process to couple the lower portions of connector pins 122a and 122b with respective SMT pads of a PCB. The vaporized foreign object(s) could cause a film similar to film 305 described above for FIG. 3 to at least partially cover upper portions of connector pins 122a and 122b. Also, other materials on around the SMT pads of the PCB could vaporize during the reflow process and the vapor could travel through bottom cavity 422 to cause a film to at least partially cover the upper portions of connector pins 122a and 122b.

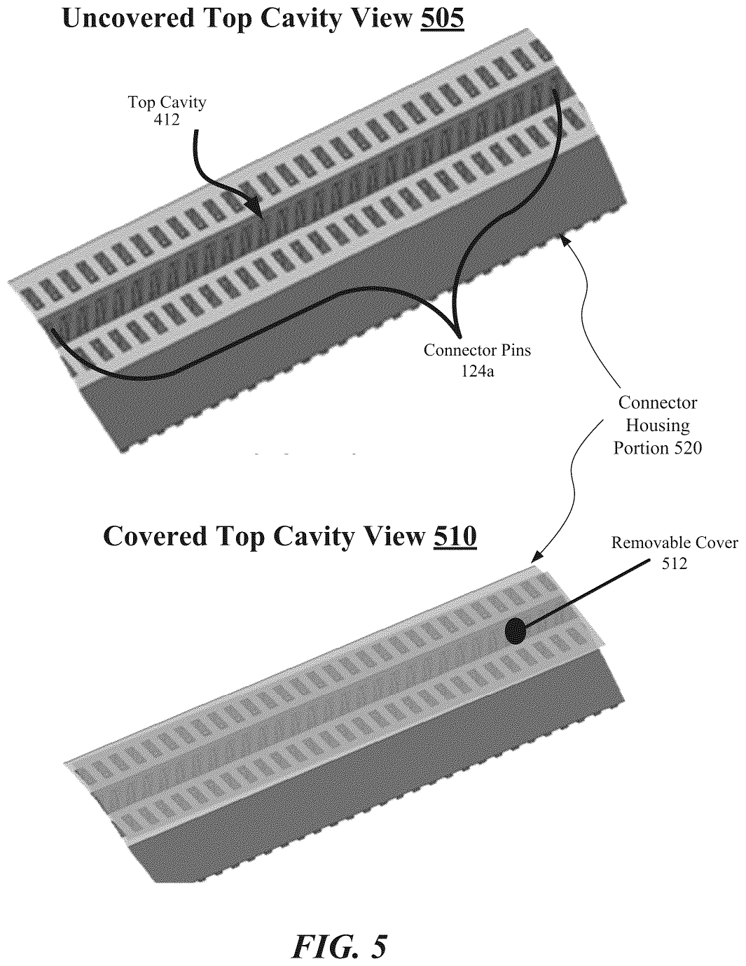

FIG. 5 illustrates example uncovered top cavity view 505 and covered top cavity view 510 of connector 120. In some examples, uncovered top cavity view 505 is a zoomed-in view of a connector housing portion 520 of connector 120 that shows top cavity 412 and upper portions of connector pins 124a. Covered top cavity view 510 shows that a removable cover 512 has been placed over top cavity 412. Although only a portion of the connector housing of connector 120 is shown in FIG. 5, the entire top cavity 412 of the full connector housing can be covered with removable cover 512.

According to some examples, removable cover 512 can be a type of high temperature tape that can maintain a cover over top cavity 412 during a reflow soldering process and then can be removed after the reflow soldering process is completed. Thus, removable cover 512 can be arranged to cover top cavity 412 before and during the reflow soldering process to prevent foreign objects from entering top cavity 412 before or during the reflow soldering process. Removable cover 512 can be, but is not limited to, a polyimide film or tape such as Kapton tape.

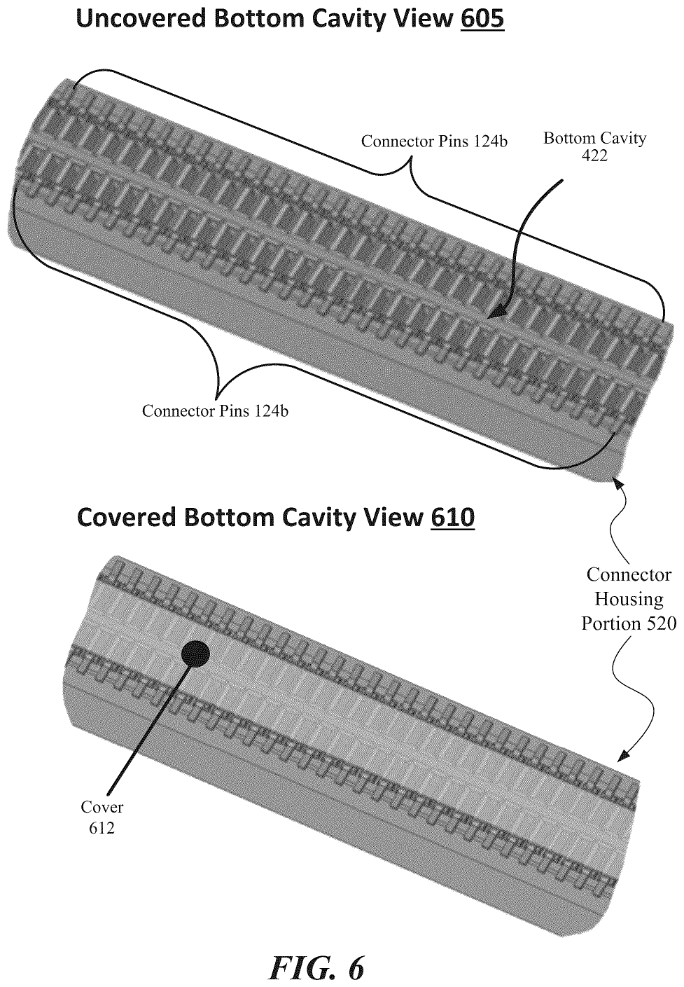

FIG. 6 illustrates example uncovered bottom cavity view 605 and covered bottom cavity view 610 of connector 120. In some examples, uncovered bottom cavity view 605 is a zoomed-in view of a bottom side of connector housing portion 520 that shows bottom cavity 422 and lower portions of connector pins 124a and 124b. Covered bottom cavity view 610 shows that a cover 612 has been placed over bottom cavity 422. Although only a portion of the connector housing of connector 120 is shown in FIG. 5, the entire bottom cavity 422 of the full connector housing can be covered with cover 612.

According to some examples, cover 612 can be a type of high temperature tape or heat-resistant plastic that can maintain a cover over bottom cavity 422 during a reflow soldering process. Thus, cover 612 can be arranged to cover bottom cavity 422 before, during and after the reflow soldering process to prevent foreign objects from entering bottom cavity 422 before or during the reflow soldering process. Also, cover 612 can inhibit or prevent vaporized materials generated during the reflow soldering process from depositing a film on the upper portions of connector pins 124a and 124b. Cover 612 can be a similar material as removable cover 512, such as but not limited to, a polyimide film or tape. Also, since cover 612 is on the bottom on the connector housing and that bottom side can be in a close proximity to a PCB following a reflow soldering process and a module will not be inserted in bottom cavity 422, a removable type of material such a polyimide tape may not be needed and a more permanent type of material can be used for cover 612 such as heat-resistant plastic that can maintain a cover over bottom cavity during the highest temperature occurring during a reflow soldering process. Types of heat-resistant plastic can include, but are not limited to, poly ether ketone, polytetrafluoroethylene or polyamide-imide. The heat-resistant plastic could be part of at least the bottom connector housing and applied to the connector via an insert molding process that exposes the lower portions of connector pins 124a and 124b outside of the connector housing but covers bottom cavity 422.

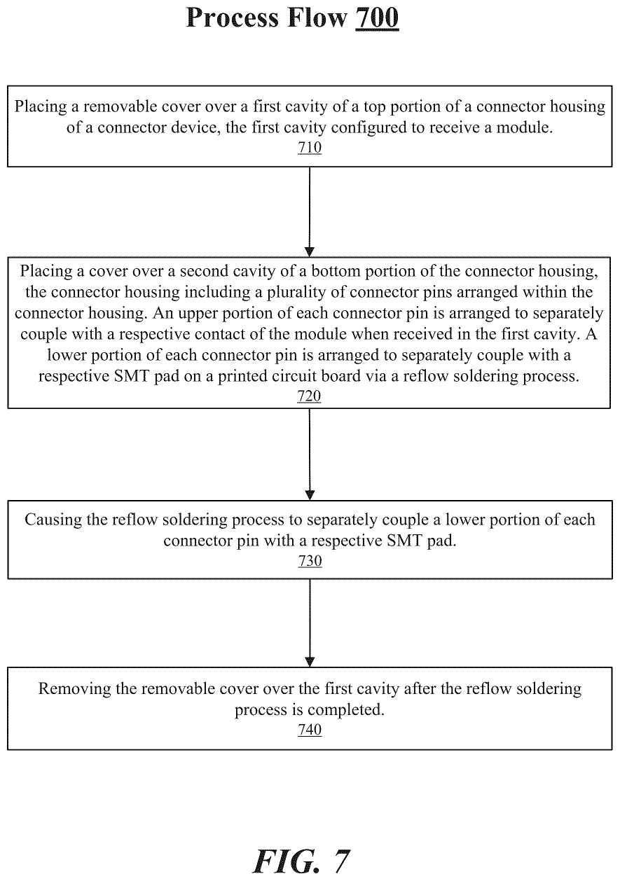

FIG. 7 illustrates an example process flow 700. According to some examples, process flow 700 describes use of a removable cover to cover a top cavity and a second cover to cover a bottom cavity of a connector housing such as described above for FIGS. 5 and 6 for connector 120.

In some examples, process flow 700 at 710 includes placing a removable cover over a first cavity of a top portion of a connector housing of a connector device, the first cavity configured to receive a module. For example, placing removable cover 512 over top cavity 412 of connector 120.

According to some examples, process flow 700 at 720 includes placing a cover over a second cavity of a bottom portion of the connector housing, the connector housing including a plurality of connector pins arranged within the connector housing. An upper portion of each connector pin is arranged to separately couple with a respective contact of the module when received in the first cavity. A lower portion of each connector pin is arranged to separately couple with a respective SMT pad on a printed circuit board via a reflow soldering process. For these examples, cover 612 can be placed over bottom cavity 422 of connector 120 that includes connector pins 124a and 124b that are to separately couple with a respective SMT pad from among SMT pads 112 via a reflow soldering process.

In some examples, process flow 700 at 730 includes causing the reflow soldering process to separately couple a lower portion of each connector pin with a respective SMT pad. For these examples, a solder reflow oven can be utilized to cause the reflow soldering process.

According to some examples, process flow 700 at 740 includes removing the removable cover over the first cavity after the reflow soldering process is completed. For these examples, removable cover 512 can be removed from cavity 412 to allow for a module to be inserted in connector 120 following completion of the reflow soldering process.

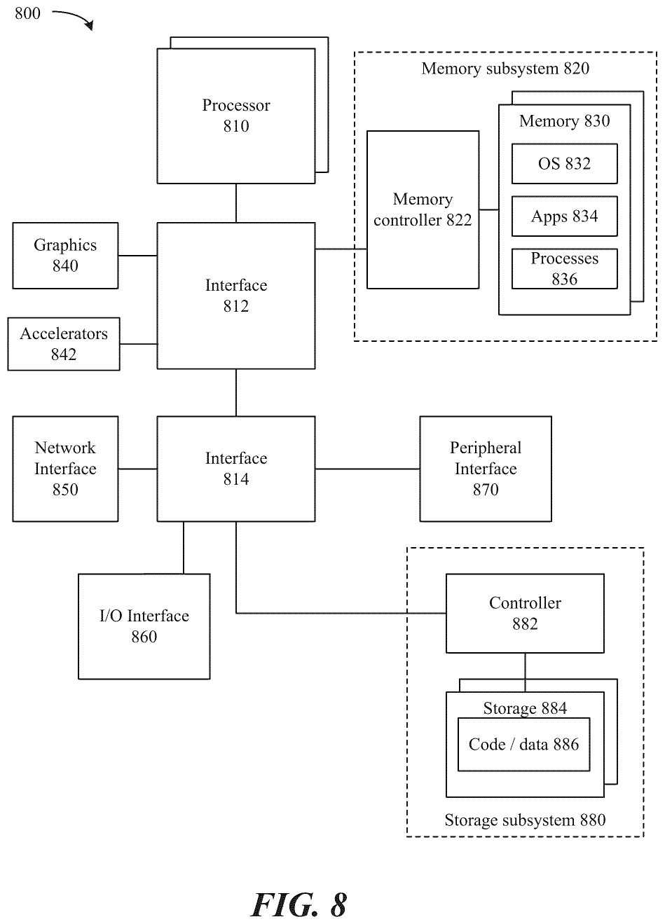

FIG. 8 illustrates an example system 800. System 800 can use examples described herein to couple a connector to a PCB (e.g., a motherboard) and that connector can couple a module used in one or more elements of a subsystem of system 800 such as memory subsystem 820 or storage subsystem 880. System 800 includes processor 810, which provides processing, operation management, and execution of instructions for system 800. Processor 810 can include any type of microprocessor, central processing unit (CPU), graphics processing unit (GPU), XPU, processing core, or other processing hardware to provide processing for system 800, or a combination of processors. An XPU can include one or more of: a CPU, a graphics processing unit (GPU), general purpose GPU (GPGPU), and/or other processing units (e.g., accelerators or programmable or fixed function FPGAs). Processor 810 controls the overall operation of system 800, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one example, system 800 includes interface 812 coupled to processor 810, which can represent a higher speed interface or a high throughput interface for system components that needs higher bandwidth connections, such as memory subsystem 820 or graphics interface components 840, or accelerators 842. Interface 812 represents an interface circuit, which can be a standalone component or integrated onto a processor die. Where present, graphics interface 840 interfaces to graphics components for providing a visual display to a user of system 800. In one example, graphics interface 840 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 840 generates a display based on data stored in memory 830 or based on operations executed by processor 810 or both. In one example, graphics interface 840 generates a display based on data stored in memory 830 or based on operations executed by processor 810 or both.

Accelerators 842 can be a programmable or fixed function offload engine that can be accessed or used by a processor 810. For example, an accelerator among accelerators 842 can provide compression (DC) capability, cryptography services such as public key encryption (PKE), cipher, hash/authentication capabilities, decryption, or other capabilities or services. In some embodiments, in addition or alternatively, an accelerator among accelerators 842 provides field select controller capabilities as described herein. In some cases, accelerators 842 can be integrated into a CPU socket (e.g., a connector to a motherboard or circuit board that includes a CPU and provides an electrical interface with the CPU). For example, accelerators 842 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs). Accelerators 842 can provide multiple neural networks, CPUs, processor cores, general purpose graphics processing units, or graphics processing units can be made available for use by artificial intelligence (AI) or machine learning (ML) models. For example, the AI model can use or include any or a combination of: a reinforcement learning scheme, Q-learning scheme, deep-Q learning, or Asynchronous Advantage Actor-Critic (A3C), combinatorial neural network, recurrent combinatorial neural network, or other AI or ML model. Multiple neural networks, processor cores, or graphics processing units can be made available for use by AI or ML models.

Memory subsystem 820 represents the main memory of system 800 and provides storage for code to be executed by processor 810, or data values to be used in executing a routine. Memory subsystem 820 can include one or more memory devices 830 such as read-only memory (ROM), flash memory, one or more varieties of random access memory (RAM) such as DRAM, or other memory devices, or a combination of such devices. Memory 830 stores and hosts, among other things, operating system (OS) 832 to provide a software platform for execution of instructions in system 800. Additionally, applications 834 can execute on the software platform of OS 832 from memory 830. Applications 834 represent programs that have their own operational logic to perform execution of one or more functions. Processes 836 represent agents or routines that provide auxiliary functions to OS 832 or one or more applications 834 or a combination. OS 832, applications 834, and processes 836 provide software logic to provide functions for system 800. In one example, memory subsystem 820 includes memory controller 822, which is a memory controller to generate and issue commands to memory 830. It will be understood that memory controller 822 could be a physical part of processor 810 or a physical part of interface 812. For example, memory controller 822 can be an integrated memory controller, integrated onto a circuit with processor 810.

While not specifically illustrated, it will be understood that system 800 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a Hyper Transport or industry standard architecture (ISA) bus, a small computer system interface (SCSI) bus, a universal serial bus (USB), or an Institute of Electrical and Electronics Engineers (IEEE) standard 1394 bus (Firewire).

In one example, system 800 includes interface 814, which can be coupled to interface 812. In one example, interface 814 represents an interface circuit, which can include standalone components and integrated circuitry. In one example, multiple user interface components or peripheral components, or both, couple to interface 814. Network interface 850 provides system 800 with the ability to communicate with remote devices (e.g., servers or other computing devices) over one or more networks. Network interface 850 can include an Ethernet adapter, wireless interconnection components, cellular network interconnection components, USB (universal serial bus), or other wired or wireless standards-based or proprietary interfaces. Network interface 850 can transmit data to a device that is in the same data center or rack or a remote device, which can include sending data stored in memory. Network interface 850 can receive data from a remote device, which can include storing received data into memory. Various embodiments can be used in connection with network interface 850, processor 810, and memory subsystem 820.

In one example, system 800 includes one or more input/output (I/O) interface(s) 860. I/O interface 860 can include one or more interface components through which a user interacts with system 800 (e.g., audio, alphanumeric, tactile/touch, or other interfacing). Peripheral interface 870 can include any hardware interface not specifically mentioned above. Peripherals refer generally to devices that connect dependently to system 800. A dependent connection is one where system 800 provides the software platform or hardware platform or both on which operation executes, and with which a user interacts.

In one example, system 800 includes storage subsystem 880 to store data in a nonvolatile manner. In one example, in certain system implementations, at least certain components of storage 880 can overlap with components of memory subsystem 820. Storage subsystem 880 includes storage device(s) 884, which can be or include any conventional medium for storing large amounts of data in a nonvolatile manner, such as one or more magnetic, solid state, or optical based disks, or a combination. Storage 884 holds code or instructions and data 886 in a persistent state (e.g., the value is retained despite interruption of power to system 800). Storage 884 can be generically considered to be a “memory,” although memory 830 is typically the executing or operating memory to provide instructions to processor 810. Whereas storage 884 is nonvolatile, memory 830 can include volatile memory (e.g., the value or state of the data is indeterminate if power is interrupted to system 800). In one example, storage subsystem 880 includes controller 882 to interface with storage 884. In one example controller 882 is a physical part of interface 814 or processor 810 or can include circuits or logic in both processor 810 and interface 814.

A power source (not depicted) provides power to the components of system 800. More specifically, power source typically interfaces to one or multiple power supplies in system 800 to provide power to the components of system 800. In one example, the power supply includes an AC to DC (alternating current to direct current) adapter to plug into a wall outlet. Such AC power can be a renewable energy (e.g., solar power) power source. In one example, power source includes a DC power source, such as an external AC to DC converter. In one example, power source or power supply includes wireless charging hardware to charge via proximity to a charging field. In one example, power source can include an internal battery, alternating current supply, motion-based power supply, solar power supply, or fuel cell source.

In an example, system 800 can be implemented using interconnected compute sleds of processors, memories, storages, network interfaces, and other components. High speed interconnects can be used such as PCle, Ethernet, or optical interconnects (or a combination thereof).

Embodiments herein may be implemented in various types of computing and networking equipment, such as switches, routers, racks, and blade servers such as those employed in a data center and/or server farm environment. The servers used in data centers and server farms can include arrayed server configurations such as rack-based servers or blade servers. These servers are interconnected in communication via various network provisions, such as partitioning sets of servers into Local Area Networks (LANs) with appropriate switching and routing facilities between the LANs to form a private Intranet. For example, cloud hosting facilities may typically employ large data centers with a multitude of servers. A blade comprises a separate computing platform that is configured to perform server-type functions, that is, a “server on a card.” Accordingly, each blade includes components common to conventional servers, including a main printed circuit board (main board) providing internal wiring (e.g., buses) for coupling appropriate integrated circuits (ICs) and other components mounted to the board.

Some examples may include an article of manufacture or at least one computer-readable medium. A computer-readable medium may include a non-transitory storage medium to store logic. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the logic may include various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner or syntax, for instructing a machine, computing device or system to perform a certain function. The instructions may be implemented using any suitable high-level, low-level, object-oriented, visual, compiled and/or interpreted programming language.

Some examples may be described using the expression “in one example” or “an example” along with their derivatives. These terms mean that a particular feature, structure, or characteristic described in connection with the example is included in at least one example. The appearances of the phrase “in one example” in various places in the specification are not necessarily all referring to the same example.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled” or “coupled with”, however, may also mean that two or more elements are not in direct contact with each other, but yet still co-operate or interact with each other.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

The follow examples pertain to additional examples of technologies disclosed herein.

Example 1. An example connector device can include a connector housing having a top portion that includes a first cavity configured to receive a module and a bottom portion that includes a second cavity. The connector device can also include a plurality of connector pins arranged within the connector housing, wherein an upper portion of each connector pin is arranged to separately couple with a respective contact of the module when received in the first cavity. A lower portion of each connector pin can be arranged to separately couple with a respective SMT pad on a printed circuit board via a reflow soldering process. The connector device can also include a removable cover arranged to cover the first cavity before and during the reflow soldering process and a cover arranged to cover the second cavity before, during and after the reflow soldering process.

Example 2. The connector device of example 1, wherein the connector device is configured according to a JEDEC specification that includes a DDR5 specification and the first cavity is configured to receive a memory module arranged to include DDR5 memory.

Example 3. The connector device of example 2, the memory module can be a DIMM.

Example 4. The connector device of example 1, the connector device can be configured according to a PCI-SIG specification that includes a PCI Express specification and the first cavity is configured to receive a PCIe card.

Example 5. The connector device of example 4, the PCI Express specification can be a PCI Express M.2 specification.

Example 6. The connector device of example 1, the removable cover can include polyimide tape.

Example 7. The connector device of example 1, the second cavity can be between the lower portion of each connector pin arranged to separately couple with a respective SMT pad and the bottom portion of the connector housing and the cover can be polyimide tape or a heat-resistant plastic.

Example 8. The connector device of example 1, the second cavity can be between the lower portion of each connector pin arranged to separately couple with a respective SMT pad and the bottom portion of the connector housing and the cover can be a same material as the connector housing.

Example 9. An example method can include placing a removable cover over a first cavity of a top portion of a connector housing of a connector device, the first cavity configured to receive a module. The method can also include placing a cover over a second cavity of a bottom portion of the connector housing, the connector housing including a plurality of connector pins arranged within the connector housing, wherein an upper portion of each connector pin is arranged to separately couple with a respective contact of the module when received in the first cavity, and wherein a lower portion of each connector pin is arranged to separately couple with a respective SMT pad on a printed circuit board via a reflow soldering process. The method can also include causing the reflow soldering process to separately couple a lower portion of each connector pin with a respective SMT pad. The method can also include removing the removable cover over the first cavity after the reflow soldering process is completed.

Example 10. The method of example 9, the connector device can be configured according to a JEDEC specification that includes a DDR5 specification and the first cavity is configured to receive a memory module arranged to include DDR5 memory.

Example 11. The method of example 10, the memory module can include a DIMM.

Example 12. The method of example 9, wherein the connector device can be configured according to a PCI-SIG specification that includes a PCI Express specification and the first cavity can be configured to receive a PCle card.

Example 13. The method of example 12, the PCI Express specification can be a PCI Express M.2 specification.

Example 14. The method of example 9, the removable cover can be polyimide tape.

Example 15. The method of example 9, the second cavity can be between the lower portion of each connector pin arranged to separately couple with a respective SMT pad and the bottom portion of the connector housing and the cover can be polyimide tape or a heat-resistant plastic.

16. The method of example 9, the second cavity can be between the lower portion of each connector pin arranged to separately couple with a respective SMT pad and the bottom portion of the connector housing and the cover can be a same material as the connector housing.

Example 17. An example system can include a printed circuit board and a connector device that includes a connector housing having a top portion that includes a first cavity configured to receive a module and a bottom portion that includes a second cavity. The connector device can also include a plurality of connector pins arranged within the connector housing. An upper portion of each connector pin can be arranged to separately couple with a respective contact of the module when received in the first cavity. A lower portion of each connector pin can be arranged to separately couple with a respective SMT pad on the printed circuit board via a reflow soldering process. The connector device can also include a removable cover arranged to cover the first cavity before and during the reflow soldering process. The connector device can also include a cover arranged to cover the second cavity before, during and after the reflow soldering process.

Example 18. The system of example 17, the connector device can be configured according to a JEDEC specification that includes a DDR5 specification and the first cavity is configured to receive a memory module arranged to include DDR5 memory.

Example 19. The system of example 18, the memory module can be a DIMM.

Example 20. The system of example 17, the connector device can be configured according to a PCI-SIG specification that includes a PCI Express specification and the first cavity can be configured to receive a PCle card.

Example 21. The system of example 20, the PCI Express specification can be a PCI Express M.2 specification.

Example 22. The system of example 17, the removable cover can be polyimide tape.

Example 23. The system of example 17, the second cavity can be between the lower portion of each connector pin arranged to separately couple with a respective SMT pad and the bottom portion of the connector housing and the cover can be polyimide tape or a heat-resistant plastic.

Example 24. The system of example 17, the second cavity can be between the lower portion of each connector pin arranged to separately couple with a respective SMT pad and the bottom portion of the connector housing and the cover can be a same material as the connector housing.

It is emphasized that the Abstract of the Disclosure is provided to comply with 37 C.F.R. Section 1.72 (b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single example for the purpose of streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus, the following claims are hereby incorporated into the Detailed Description, with each claim standing on its own as a separate example. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A connector device comprising:
a connector housing having a top portion that includes a first cavity configured to receive a module and a bottom portion that includes a second cavity;
a plurality of connector pins arranged within the connector housing, wherein an upper portion of each connector pin is arranged to separately couple with a respective contact of the module when received in the first cavity, and wherein a lower portion of each connector pin is arranged to separately couple with a respective surface mount technology (SMT) pad on a printed circuit board via a reflow soldering process;
a removable cover arranged to cover the first cavity before and during the reflow soldering process; and
a cover arranged to cover the second cavity before, during and after the reflow soldering process.

2. The connector device of claim 1, wherein the connector device is configured according to a Joint Electronic Device Engineering Council (JEDEC) specification that includes a double data rate version 5 (DDR5) specification and the first cavity is configured to receive a memory module arranged to include DDR5 memory.

3. The connector device of claim 2, wherein the memory module comprises a dual in-line memory module (DIMM).

4. The connector device of claim 1, wherein the connector device is configured according to a Peripheral Component Interconnect Special Interest Group (PCI-SIG) specification that includes a PCI Express specification and the first cavity is configured to receive a PCle card.

5. The connector device of claim 4, wherein the PCI Express specification is a PCI Express M.2 specification.

6. The connector device of claim 1, wherein the removable cover comprises polyimide tape.

7. The connector device of claim 1, wherein the second cavity is between the lower portion of each connector pin arranged to separately couple with a respective SMT pad and the bottom portion of the connector housing and the cover is polyimide tape or a heat-resistant plastic.

8. The connector device of claim 1, wherein the second cavity is between the lower portion of each connector pin arranged to separately couple with a respective SMT pad and the bottom portion of the connector housing and the cover is a same material as the connector housing.

9. A method comprising:
placing a removable cover over a first cavity of a top portion of a connector housing of a connector device, the first cavity configured to receive a module;
placing a cover over a second cavity of a bottom portion of the connector housing, the connector housing including a plurality of connector pins arranged within the connector housing, wherein an upper portion of each connector pin is arranged to separately couple with a respective contact of the module when received in the first cavity, and wherein a lower portion of each connector pin is arranged to separately couple with a respective surface mount technology (SMT) pad on a printed circuit board via a reflow soldering process;
causing the reflow soldering process to separately couple a lower portion of each connector pin with a respective SMT pad; and
removing the removable cover over the first cavity after the reflow soldering process is completed.

10. The method of claim 9, wherein the removable cover comprises polyimide tape.

11. The method of claim 9, wherein the second cavity is between the lower portion of each connector pin arranged to separately couple with a respective SMT pad and the bottom portion of the connector housing and the cover is polyimide tape or a heat-resistant plastic.

12. The method of claim 9, wherein the second cavity is between the lower portion of each connector pin arranged to separately couple with a respective SMT pad and the bottom portion of the connector housing and the cover is a same material as the connector housing.

13. A system comprising:
a printed circuit board; and
a connector device that includes:
a connector housing having a top portion that includes a first cavity configured to receive a module and a bottom portion that includes a second cavity;
a plurality of connector pins arranged within the connector housing, wherein an upper portion of each connector pin is arranged to separately couple with a respective contact of the module when received in the first cavity, and wherein a lower portion of each connector pin is arranged to separately couple with a respective surface mount technology (SMT) pad on the printed circuit board via a reflow soldering process;
a removable cover arranged to cover the first cavity before and during the reflow soldering process; and
a cover arranged to cover the second cavity before, during and after the reflow soldering process.

14. The system of claim 13, wherein the connector device is configured according to a Joint Electronic Device Engineering Council (JEDEC) specification that includes a double data rate version 5 (DDR5) specification and the first cavity is configured to receive a memory module arranged to include DDR5 memory.

15. The system of claim 14, wherein the memory module comprises a dual in-line memory module (DIMM).

16. The system of claim 13, wherein the connector device is configured according to a Peripheral Component Interconnect Special Interest Group (PCI-SIG) specification that includes a PCI Express specification and the first cavity is configured to receive a PCle card.

17. The system of claim 16, wherein the PCI Express specification is a PCI Express M.2 specification.

18. The system of claim 13, wherein the removable cover comprises polyimide tape.

19. The system of claim 13, wherein the second cavity is between the lower portion of each connector pin arranged to separately couple with a respective SMT pad and the bottom portion of the connector housing and the cover is polyimide tape or a heat-resistant plastic.

20. The system of claim 13, wherein the second cavity is between the lower portion of each connector pin arranged to separately couple with a respective SMT pad and the bottom portion of the connector housing and the cover is a same material as the connector housing.
